(19) United States
(12) Patent Application Publication
(10) Pub. No.: US 2025/0222496 A1
(43) Pub. Date: Jul. 10, 2025

(54) METHOD FOR CLEANING AN APPARATUS FOR A TIN COMPOUND AND THE CLEANED APPARATUS OBTAINED THEREBY

(71) Applicants: Mitsubishi Chemical Corporation, Tokyo (JP); Gelest, Inc., Morrisville, PA (US); Taiyo Nippon Sanso Corporation, Tokyo (JP)

(72) Inventors: Koki ISHII, Tokyo (JP); Hiroshi FUKUI, Tokyo (JP); Takashi KAMEOKA, Tokyo (JP); Li YANG, Belle Mead, NJ (US)

(21) Appl. No.: 19/000,257

(22) Filed: Dec. 23, 2024

Related U.S. Application Data
(60) Provisional application No. 63/617,781, filed on Jan. 5, 2024.

(51) Int. Cl. B08B 9/08; C11D 7/08; C11D 7/50

(52) U.S. Cl. CPC B08B 9/08; C11D 7/08; C11D 7/5022; C11D 7/5027; B08B 2209/08

(57) ABSTRACT

A method for efficiently and safely cleaning an apparatus for tin compound and a highly purified tin compound apparatus are provided. A cleaning method for an apparatus that has been in contact with a tin compound having formula (1) below includes at least steps (A) to (C), in which step (B) is performed after step (A), and step (C) is performed after step (B):
(A) a step of cleaning the apparatus with a non-protic solvent,
(B) a step of cleaning the apparatus with alcohol, and
(C) a step of cleaning the apparatus with ultrapure water having a resistivity value of 17 MΩ·cm at 25° C.

RₚSnXₘ (1)

In formula (1), R is a hydrocarbon group, p is an integer from 1 to 3, X is a hydrolyzable substituent, and m=4−p.

### CROSS-REFERENCE TO RELATED APPLICATION

This application claims priority to co-pending U.S. Provisional Application No. 63/617,781, filed Jan. 5, 2024, the disclosure of which is herein incorporated by reference in its entirety.

### SUMMARY OF THE INVENTION

### Technical Field

The present invention relates to a method for cleaning an apparatus for a tin compound and the cleaned apparatus obtained thereby, and more particularly to a method for efficiently and safely cleaning an apparatus for a tin compound and the highly purified apparatus obtained thereby.

### Background Art

In recent years, with the advancement of highly information-oriented society, there is a demand for handling more information at higher speeds and with higher accuracy, and the technology related to semiconductor integrated circuits and semiconductor devices has been making remarkable progress day by day.

Conventional chemically amplified resists (CARs) have potential drawbacks when used in EUV lithography, particularly due to their low absorption coefficients in the EUV region, which can lead to diffusion blurring of photoactive species or line edge roughness. Therefore, there remains a need for improved EUV photoresist materials with characteristics such as thinner thickness, better absorbance, and superior etching resistance.

For this reason, liquid CVD materials such as tin compounds have recently begun to be used as photoresists, especially for EUV, and it has become necessary to require extremely high purity to achieve high-quality film formation. Therefore, tin compounds need to be purified by removing impurities such as water, residual solvents used in synthesis, and metal impurities by distillation (Patent Literature 1), and it is necessary to avoid the intrusion of impurities as much as possible.

### PRIOR ART LITERATURE

[Patent Literature 1] Patent Publication No. JP2020-530199

### PROBLEMS TO BE SOLVED BY THE INVENTION

However, tin compounds react with oxygen and water to form stanoxane compounds, which may adhere to and remain on an apparatus for tin compound, becoming impurities in subsequent synthesis or storage, or potentially causing a decrease in the purity of tin compounds.

Therefore, in view of the above background, the present invention aims to provide a method for efficiently and safely cleaning an apparatus for a tin compound and a highly purified apparatus for a tin compound.

### MEANS FOR SOLVING THE PROBLEMS

The present inventors have made intensive studies to solve these problems and have found that by subjecting an apparatus that has come into contact with a specific tin compound and has impurities attached to it to a special cleaning process, it is possible to efficiently and safely clean the apparatus.

That is, the present invention has the following aspects.

[1]

A method for cleaning an apparatus that has come into contact with a tin compound having formula (1), the method comprising at least steps (A) to (C), wherein step (B) is performed after step (A), and step (C) is performed after step (B):
(A) a step of cleaning the apparatus with a non-polar solvent,
(B) a step of cleaning with an alcohol, and
(C) a step of cleaning the apparatus with ultrapure water with a resistivity of 17 MΩ·cm at 25° C.,

RₚSnXₘ (1)

wherein R is a hydrocarbon group, p is an integer from 1 to 3, X is a hydrolysable substituent group, and m=4−p.
[2]

The method for cleaning a tin compound apparatus as claimed in [1], further comprising a step of cleaning with an acidic aqueous solution following the step of cleaning with an alcohol.

[3]

The method for cleaning a tin compound apparatus as claimed in [1] or [2], wherein the non-polar solvent comprises at least one solvent selected from the group consisting of aromatic hydrocarbons, aliphatic hydrocarbons, saturated cyclic hydrocarbons, esters, linear ethers, and cyclic ethers.

[4]

The method for cleaning a tin compound apparatus as claimed in any one of [1] to [3], wherein the number of carbon atoms in the alcohol is 1 to 12.

[5]

The method for cleaning a tin compound apparatus as claimed in any one of [2] to [4], wherein the acidic aqueous solution is at least one solution selected from the group consisting of a hydrofluoric acid aqueous solution and a nitric acid aqueous solution.

[6]

The method for cleaning a tin compound apparatus as claimed in any one of [1] to [5], further comprising a drying step after the step of cleaning with ultrapure water.

[7]

The method for cleaning a tin compound apparatus as claimed in claim 1 or 2, wherein the tin compound having formula (1) is t-butyltris (dimethylamino)tin, n-butyltris (dimethylamino)tin, t-butyltris (diethylamino)tin, di-t-butylbis (dimethylamino)tin, sec-butyltris (dimethylamino)tin, n-pentyltris (dimethylamino)tin, isobutyltris (dimethylamino)tin, isopropytris (dimethylamino)tin, t-butyltri-t-butoxytin, n-butyltri-t-butoxytin, isopropyltri-t-butoxytin, isopropyltri-t-amyloxytin, t-butyltri-t-amyloxytin, 1-methyl-1-cyclopentyltris (dimethylamino)tin, or 1-methyl-1-cyclopentyltri-t-butoxytin.

[8]

An apparatus that has come into contact with the tin compound having formula (1) and has been cleaned by the method as claimed in any one of [1] to [7].

[9]

The apparatus for a tin compound as claimed in [8], wherein when ultrapure water with a resistivity of 17 MΩ·cm at 25° C. is filled into the apparatus for a tin compound and left at 25° C. for 1 hour, an increase in the amount of dissolved halogen ions in the water is 100 mass ppb or less, an increase in the amount of each metal element sodium, potassium, magnesium, iron, chromium, and nickel is 1.5 mass ppb or less, and the increase in the amount of particles with a diameter of 0.5 μm or more is 100 particles/mL or less.

[10]

The apparatus for a tin compound as claimed in [8] or [9], wherein when the tin compound having formula (1) is placed in the apparatus for a tin compound, sealed under an inert gas atmosphere, and stored at 25° C. for 3 months, the decrease in the purity of the tin compound is 0.1 mass % or less.

[11]

A container for storing a tin compound, which is the apparatus for a tin compound as claimed in any one of [8] to [10].

[12]

The apparatus for a tin compound as claimed in any one of [8] to [11], wherein when the apparatus is vacuum-dried and then filled with a gas with a pressure of 10 kPa, a valve seat leakage at the joint part measured by a gas detection device is 5×10⁻⁹Pam³/s or less.

[13]

An apparatus for a tin compound, wherein when ultrapure water with a resistivity of 17 MΩ·cm at 25° C. is filled into the apparatus and left at 25° C. for 1 hour, an increase in the amount of dissolved halogen ions in the water is 100 mass ppb or less, and a content of metal elements other than tin is 1.5 mass ppb or less.

[14]

An apparatus for a tin compound, wherein when ultrapure water with a resistivity of 17 MΩ·cm at 25° C. is filled into the apparatus and left at 25° C. for 1 hour, an increase in the amount of particles with a diameter of 0.5 μm or more is 100 particles/mL or less.

### ADVANTAGEOUS EFFECTS OF THE INVENTION

The method for cleaning a tin compound apparatus according to the present disclosure makes it possible to efficiently and safely clean the apparatus. Furthermore, the cleaned apparatus obtained by the method according to the present disclosure is highly purified, and the occurrence of impurities is suppressed, resulting in an apparatus that does not cause a decrease in the purity of the tin compound.

### EMBODIMENTS FOR CARRYING OUT THE INVENTION

The present invention will be described below based on examples of embodiments of the present invention. However, the present invention is not limited to the following embodiments.

Unless otherwise stated, any numerical value is to be understood as being modified in all instances by the term “about.” Thus, a numerical value typically includes ±10% of the recited value. For example, the recitation of a temperature such as “10° C.” or “about 10° C.” includes 9° C. and 11° C. and all temperatures there between.

All numerical ranges expressed in this disclosure expressly encompass all possible subranges, all individual numerical values within that range, including integers within such ranges and fractions and decimal amounts of the values unless the context clearly indicates otherwise.

Note that, in the present invention, when expressing “α to β” (α and β are arbitrary numbers), unless otherwise specified, it includes the meaning of “α or more and β or less” together with the meaning of “preferably larger than α” or “preferably smaller than β”. Also, when expressing “α or more” (α is an arbitrary number) or “β or less” (β is an arbitrary number), it includes the meaning of “preferably larger than α” or “preferably smaller than β”. Furthermore, “γ and/or δ (γ, δ are arbitrary components)” means that it means at least one of γ and δ, and means three types of γ only, δ only, and γ and δ.

One embodiment of the present invention relating to a method for cleaning an apparatus for a tin compound (hereinafter sometimes referred to as “the present cleaning method”) is a method for cleaning an apparatus that has come into contact with a tin compound having formula (1) below, comprising at least the following steps (A) to (C), wherein step (B) is performed after step (A), and step (C) is performed after step (B):
(A) a step of cleaning the apparatus with a non-polar solvent,
(B) a step of cleaning the apparatus with an alcohol, and
(C) a step of cleaning the apparatus with ultrapure water with a resistivity of 17 MΩ·cm at 25° C.;

RₚSnXₘ (1)

In formula (1), R is a hydrocarbon group, p is an integer from 1 to 3, X is a hydrolysable substituent group, and m=4−p.

### Specific Tin Compound

The present cleaning method is applied to an apparatus that has come into contact with a specific tin compound. The tin compound according to the present invention means a tin compound represented by the general formula “RₚSnXₘ.”

In the above formula, “R” is a hydrocarbon group, preferably a hydrocarbon group with a carbon number of 1 to 30, more preferably a hydrocarbon group with a carbon number of 1 to 15, more preferably a hydrocarbon group with a carbon number of 1 to 10, and further preferably a hydrocarbon group with a carbon number of 2 to 6. Examples of saturated hydrocarbon groups include a methyl group, ethyl group, n-propyl group, isopropyl group, n-butyl group, isobutyl group, t-butyl group, 1-methylpropyl group, etc., and examples of unsaturated hydrocarbon groups include a vinyl group, 2-propenyl group, etc. Examples of aromatic hydrocarbon groups include a phenyl group, tolyl group, benzyl group, phenethyl group, etc.

Also, in the above formula, “X” means a hydrolysable substituent group, such as halogen, N-amino group, alkoxy group (—OR′), alkynide group (R′C═C), azido group (N₃—), dialkylamino group (—NR′₂)(—NR′R″), N-alkylacylamino group (—N(R′)C(O)R′)(—N(R′)C(O)R″)(—N(R″)C(O)R′), acyloxy group (—OCOR′), N-acylamino group (—N(H)C(O)R′), etc. R′and R″ are each independently a hydrocarbon group with a carbon number of 1 to 10. Among them, X is preferably a dialkylamino group, an alkoxy group, an N-alkylacylamino group, halogen, or an acyloxy group, more preferably a dialkylamino group or an alkoxy group, and particularly preferably a dialkylamino group (—NR′₂) or an alkoxy group (—OR′). Furthermore, in the above formula, “p” is an integer from 1 to 3, and “m” is 4−p.

Among the above tin compounds, a tin compound having formula (2) below (sometimes referred to as “monoalkyltin compound”) is particularly preferred.

RSnX₃ (2)

In formula (2), R is a hydrocarbon group with a carbon number of 1 to 30, and X represents a hydrolysable substituent group.

Examples of compounds having formula (2) include t-butyltris(dimethylamino)tin, n-butyltris (dimethylamino)tin, t-butyltris(diethylamino)tin, sec-butyltris (dimethylamino)tin, n-pentyltris(dimethylamino)tin, isobutyltris(dimethylamino)tin, isopropyltris(dimethylamino)tin, t-butyltri-t-butoxytin, n-butyltri-t-butoxytin, isopropyltri-t-butoxytin, isopropyltri-t-amyloxytin, t-butyltri-t-amyloxytin, 1-methyl-1-cyclopentyltris (dimethylamino)tin, 1-methyl-1-cyclopentyltri-t-butoxytin, etc.

The molecular weight of the above tin compound is usually 200 to 900. When used for CVD, it is necessary to have a certain vapor pressure, and therefore, it is preferably 240 to 700, more preferably 260 to 600, and particularly preferably 280 to 500.

The tin compound may be a single compound or a mixture of two or more types of compounds. When two or more tin compounds are mixed, it is preferable that the difference in molecular weight between the two compounds is 100 or less, since they can be simultaneously volatilized in the CVD film formation process, and it is more preferable that the difference is 50 or less, further preferably 30 or less, and particularly preferably 15 or less. It is also preferable that the mixture be a mixture of isomers with the same molecular weight for the same reason.

When mixing two or more types of tin compounds, it is desirable that the purity of each tin compound is 99.8% or more.

### Tin Compound Apparatus

The tin compound apparatus which is encompassed by the cleaning method described herein includes all devices or apparatuses that come into contact with the tin compound in all industrial processes, such as synthesis, purification, storage (preservation), etc. of the tin compound. Examples of the tin compound device include, for example, a synthesis device, a distillation purification device, a filtration device, a container for storage or preservation, a pipe for connecting these, etc. The capacity of the device, especially the capacity of the container, is usually 0.1 to 100 L, and from the viewpoint of easily achieving the effect of the present invention, 0.1 to 30 L is preferable, more preferably 0.5 to 10 L.

These devices and pipes, etc. are usually made of stainless steel, but may also be formed of corrosion-resistant alloys such as nickel-based alloys, for example, Inconel. In order to improve the corrosion resistance of the inside of the container or pipe made of a metal material, the inside of the container or pipe may be coated with a resin material such as a fluororesin.

The above tin compound reacts with oxygen and water to produce stanoxane compounds, low molecular weight oxidized tin compounds, and other impurities, which are the causes of scale. In order to efficiently remove such tin impurities from the apparatus the present cleaning method includes the following cleaning steps.

### Non-Polar Solvent Cleaning Step (A)

In the non-polar solvent cleaning step (A), the device is cleaned with a non-polar solvent. The tin compound attached to the device is dissolved in the non-polar solvent and washed away. Also, stanoxane compounds (the cause of scale and adhesion) remaining in the device do not dissolve in the non-polar solvent, but can be physically washed away in this non-polar solvent cleaning step.

When X in formula (1) has a highly hydrolyzable group, for example, a dialkylamino group, there is a tendency to easily produce stanoxane compounds, and the cleaning effect of the present invention tends to be more effectively obtained.

Appropriate non-polar solvents that can be used include aromatic hydrocarbons such as toluene, xylene, and benzene; aliphatic hydrocarbons such as hexane and heptane; saturated cyclic hydrocarbons such as cyclohexane and methylcyclohexane; esters such as methyl acetate, ethyl acetate, and propyl acetate; linear ethers such as diethyl ether, diisopropyl ether, methyl-t-butyl ether, cyclopentylmethyl ether, and diphenyl ether; cyclic ethers such as tetrahydrofuran, 1,4-dioxane, etc. These solvents can be used alone or in a mixture of two or more.

The cleaning method is not particularly limited, and known cleaning methods for devices used for compound synthesis and storage can be appropriately adopted. For example, if it is a synthesis device, the method may involve attaching a recovery valve after sending the reaction product to the next process, filling the reaction container with a non-polar solvent, and recovering the non-polar solvent from the recovery valve. Also, after disassembling the device, it is possible to perform washing, immersion, wiping, etc. with a non-polar solvent. When washing with a non-polar solvent, it is also possible to improve the cleaning effect by spraying the non-polar solvent together with nitrogen or air, and it is also possible to apply ultrasonic vibration when filling the device with a solvent or immersing the device in a solvent. It is also possible to perform different cleaning methods in combination.

The atmosphere during cleaning is preferably an environment with a reduced oxygen concentration or an inert gas atmosphere such as nitrogen, helium, or argon to prevent the toxicity and risk of ignition of decomposition products, such as amines, that may be generated during cleaning. In such an environment, there is no particular limitation, but for example, it is preferable to perform cleaning in a nitrogen atmosphere with an oxygen concentration of 0.1 volume % or less that has passed through a gas filter.

The number of cleaning times or cycles is not particularly limited, and it is possible to perform cleaning once, but in order to obtain a sufficient cleaning effect, it is preferably performed 2 to 5 times. The cleaning temperature is also not particularly limited, and it is preferably 0 to 70° C., more preferably 0 to 50° C., and further preferably 10 to 30° C. The amount of non-polar solvent used during cleaning is preferably 0.1 to 10.0 L/m² as the amount of use per cleaned area, more preferably 0.2 to 5.0 L/m², and further preferably 0.2 to 2.0 L/m².

### Alcohol Cleaning Step (B)

In the alcohol cleaning step (B), the apparatus cleaned in the non-protic solvent cleaning step (A) is cleaned using an alcohol. This step may involve cleaning the device by dissolving polar decomposition products derived from tin compounds that could not be removed in the non-protic solvent cleaning step (A), or through physical action.

The alcohol is not particularly limited and may be aliphatic alcohols, alicyclic alcohols, and aromatic alcohols, and may be either monoalcohols or polyalcohols. Among these, aliphatic monoalcohols are preferred, such as methanol, ethanol, propanol, isopropanol, n-butanol, isobutanol, sec-butanol, t-butanol, 1-pentanol, 2-pentanol, 3-pentanol, cyclopentanol, 1-hexanol, 2-hexanol, 3-hexanol, 1-heptanol, 2-heptanol, 3-heptanol, 1-octanol, isooctanol, 2-ethylhexanol, isononyl alcohol, lauryl alcohol, etc. The number of carbon atoms in the alcohol is preferably 1 to 12, more preferably 1 to 6, even more preferably 1 to 3, and is particularly preferably methanol. These alcohols may have substituents such as alkyl groups and these alcohols may be used alone or as a mixture of two or more.

In alcohol cleaning, it is preferable to use an alcohol as the main component of the cleaning agent, and it is preferable to use only alcohol from the viewpoint of the solubility of the tin compound. Here, “main component” refers to the most abundant component in the cleaning agent, and it is usually 50% by mass or more, preferably 90% by mass or more, and most preferably 100% by mass.

The cleaning method, atmosphere during cleaning, number of cleaning times, cleaning temperature, and amount of cleaning liquid used are the same as in the non-polar solvent cleaning step (A).

### Acid Aqueous Solution Cleaning Step

In an optional acid aqueous solution cleaning step, the device cleaned in the alcohol cleaning step (B) is cleaned with an acid aqueous solution. In this step, the remaining residue that could not be dissolved in the alcohol cleaning step (B) is used to dissolve the residue, and, for example, is used to dissolve the scale and the like that have accumulated in the joints, recesses, and scratches of the device, thereby cleaning the device.

The acid aqueous solution is not particularly limited as long as it is an acid aqueous solution with a pH of less than 7, but preferably has a pH of 6 or less, more preferably a pH of 5 or less. The solution is preferably at least one selected from the group consisting of a hydrofluoric acid aqueous solution and a nitric acid aqueous solution, and more preferably a nitric acid aqueous solution.

In the case of a nitric acid aqueous solution, a concentration in the range of 25 to 80% by mass is preferable, and more preferably 30 to 70% by mass. In the case of a hydrofluoric acid aqueous solution, a concentration of 0.5 to 1% by mass is preferable, and these combinations may also be used. When using a hydrofluoric acid aqueous solution in this step, if the device contains stainless steel, it has corrosiveness, and therefore it is not always necessary to apply it to every cleaning step because it usually requires more frequent ultrapure water cleaning steps than usual.

The cleaning method, atmosphere during cleaning, number of cleaning times, cleaning temperature, and amount of cleaning liquid used are the same as in the non-polar solvent cleaning step (A).

### Ultrapure Water Cleaning Step (C)

The ultrapure water cleaning step (C) is performed after the alcohol cleaning step (B) and after the optional acid aqueous solution cleaning step, and is a step of removing impurities and fine particles remaining in the device.

The cleaning liquid used in the ultrapure water cleaning step (C) is ultrapure water with a resistivity of 17 MΩ·cm at 25° C. The resistivity of theoretical pure water is 18.24 MΩ·cm, but from the point of view of production efficiency, it is preferable for the resistivity of the water used in the methods of the present disclosure to be 17 MΩ·cm. The resistivity can be measured, for example, with a commercially available electrical conductivity meter.

The cleaning method, number of cleaning times, cleaning temperature, and amount of cleaning liquid used are the same as in the non-polar solvent cleaning step (A). It is preferable to perform the ultrapure water cleaning step within the ultrapure water in a class 1000-level clean room. It is preferable for the ultrapure water cleaning step (C) to be the final cleaning step. It is preferable to perform all of the above cleaning steps under an inert gas atmosphere such as nitrogen, helium, or argon because there is a tendency for the tin compound to be difficult to clean due to the solidification of the stanoxane (dirt) caused by the hydrolysis of the tin compound under atmospheric conditions.

### Drying Process

After the ultrapure water cleaning process (C), a drying process may be performed to dry the apparatus for a tin compound. The drying process may be carried out by injecting or inserting chemical-clean level inert gas (such as pure nitrogen). For example, to completely remove moisture when using nitrogen gas, the drying may include continually replacing the gas in the apparatus with gas heated to 60° C. until it is confirmed that the dew point temperature reaches −60° C. (10 ppm by volume).

### Tin Compound Apparatus After Cleaning

Embodiments of the disclosure also include a tin compound apparatus cleaned by the cleaning method described herein. The tin compound apparatus according to one embodiment of this invention is highly purified, so it is preferably used as a container for storing high-purity tin compounds after purification.

This storage container (not limited to storage containers, but including any tin compound apparatus that can hold water) has the following characteristics when filled with ultrapure water with a specific resistivity of 17 MΩ·cm at 25° C. (used as the cleaning liquid in the ultrapure water cleaning process (C)) and left standing for 1 hour at 25° C.: Typically, the increase in halogen ions in the water is 100 mass ppb or less, the increase in particles 0.5 μm or larger is 100 particles/mL or less, and the content of metal elements other than tin, specifically sodium, magnesium, nickel, chromium, potassium, and iron, is 1.5 mass ppb or less for each element. In other words, the water after being put in the container is barely contaminated after being put into the container relative to its purity prior to being put in the container.

Preferably, the increase in halogen ions is 50 mass ppb or less, more preferably 30 mass ppb or less. The increase in particles 0.5 μm or larger is preferably 50 particles/mL or less, more preferably 10 particles/mL or less. Also, the content of metal elements other than tin, specifically sodium, magnesium, nickel, chromium, potassium, and iron, is preferably 1.5 mass ppb or less for each element. The methods for quantifying halogen ions and metal elements, and for measuring particles 0.5 μm or larger, will be described later in the examples.

As described above, the tin compound apparatus of this embodiment is highly purified, so even when storing tin compounds, the tin compounds are not adversely affected by impurities from the apparatus and their purity does not significantly decrease. For example, when a tin compound is placed in a storage container under an inert gas atmosphere, sealed, and stored at 25° C. for 3 months, preferably at 45° C., the decrease in the purity of the tin compound is 0.1 mass % or less. Examples of inert gases include argon, helium, and nitrogen, with nitrogen being preferred. When using nitrogen as the inert gas, it is preferable to keep the oxygen concentration in the nitrogen atmosphere at 1 ppm or less (by volume) and the dew point at −60° C. (10 ppm by volume) or lower. This is because the presence of oxygen and moisture tends to lead to a decrease in the purity of tin compounds.

When the tin compound apparatus is a container, it is preferable to have high sealing properties so that it may be used as a container for storing high-purity tin compounds after purification. To confirm the airtightness of the container, it is preferable to perform a helium leak test using a helium detector after the above drying process.

The leak test method is typically performed as follows:
1. After purging the tin compound apparatus with helium multiple times (usually 2 times, preferably 3 times), fill it with helium to 345 kPa using an air-operated valve, hold for 4 hours, and confirm there are no leaks.
2. For containers, after completely drying the container and putting it under vacuum once, fill it with helium to an internal pressure of 34.5 kPa, connect a helium detector, and check the valve seat leakage. The area to check for valve seat leakage is, for example, the connector joint.

The amount of helium leakage is typically 5×10⁻⁹Pa·m³/s or less, preferably 1×10⁻⁹Pa·m³/s or less.

### EXAMPLES

The following examples further illustrate the present invention, but the invention is not limited to these examples as long as it does not exceed its essence.

### Quantification of Halogen Ions

An ion chromatograph (ISC-3000, manufactured by Nippon Dionex) was used.

### Content of Particles 0.5 μm or Larger

The number of particles 0.5 μm or larger was measured using a particle counter utilizing laser light scattering (AZ-SO2/LS-200, manufactured by Particle Measuring Systems (PMS)).

### Quantification of Metal Elements

Metal elements were quantified using ICP-MS (inductively coupled plasma mass spectrometer, Agilent 7700, manufactured by Agilent Technologies).

### Purity of isopropyltris(dimethylamino)tin

About 1 g of isopropyltris(dimethylamino)tin was weighed and placed in an NMR tube with an inner diameter of 5 mm, and quantified using ¹¹⁹Sn-NMR spectrum. The equipment and conditions used were as follows:
Equipment: JNM-ECZ400S (manufactured by JEOL)
Measurement temperature: 30° C.
Relaxation time: 6 seconds
Number of accumulations: 5000

### Example 1

Isopropyltris(dimethylamino)tin (99.8 mol % purity) was prepared. A 1000 mL SUS316L container was prepared as its storage container. In a glove box under nitrogen atmosphere, 500 mL of isopropyltris(dimethylamino)tin was placed in the storage container, left for 48 hours, then removed from the container, and the container was dried.

n-Hexane was prepared, and in a simple glove box with oxygen concentration of 1 ppm or less under nitrogen atmosphere, the storage container was rinsed to perform the non-protic solvent cleaning process. The rinsing was done 3 times with 1000 mL each time.

Methanol was prepared, and in a simple glove box under nitrogen atmosphere, the storage container was rinsed to perform the alcohol cleaning process. The rinsing was done 3 times with 1000 mL each time.

Ultrapure water (resistivity at 25° C.: 17 MΩ·cm) was prepared, and in a simple glove box under nitrogen atmosphere, the storage container was rinsed to perform the ultrapure water cleaning process. The rinsing was done 3 times with 1000 mL each time.

The cleaned storage container was filled with ultrapure water (resistivity at 25° C.: 17 MΩ·cm), sealed, and left standing at 25° C. for 1 hour. Compared to the ultrapure water before filling, the increase in halogen ions was 50 mass ppb, and the increase in particles 0.5 μm or larger was 30 particles/mL.

The metal elements in the filled ultrapure water were quantified using ICP-MS, and the results are shown in Table 1 below. The content of metal elements was all 1.5 mass ppb or less. When observing the inside of the container with a Borescope, a small amount of yellowish precipitate was observed.

TABLE 1
(mass ppb)

| Na | Mg | K | Cr | Fe | Ni |
|---|---|---|---|---|---|
| 0.02 | 0.01 | 0.02 | 0.01 | 0.11 | 0.14 |

After cleaning the tin compound storage container, the following experiment was conducted in a clean zone to confirm its airtightness. Helium was filled into the container through an air-operated valve, and the filling and evacuation process (helium purge) was repeated 3 times, then helium was filled to 345 kPa. It was confirmed that there were no leaks over the next 4 hours.

The tin compound storage container was completely dried by vacuum suction at 60° C. for 24 hours, then cooled to 25° C., vacuum suctioned again, and helium was introduced up to 34.5 kPa.

The leakage from the VCR (valve seat) was measured using a helium detector connected with VCR® and KF adapters manufactured by Cosmo Tech, resulting in 5×10−10Pa·m³/s.

### Example 2

Isopropyltris(dimethylamino)tin (99.8 mass % purity) was prepared. A 1000 mL SUS316L container was prepared as its storage container. In a glove box under nitrogen atmosphere, 500 mL of isopropyltris(dimethylamino)tin was placed in the storage container, left for 48 hours, then removed from the container, and the container was dried.

n-Hexane was prepared, and in a simple glove box under nitrogen atmosphere with oxygen concentration of 0.1 vol % or less, the storage container was rinsed to perform the non-protic solvent cleaning process. The rinsing was done 3 times with 1000 mL each time.

Methanol was prepared, and in a simple glove box under nitrogen atmosphere with oxygen concentration of 0.1 vol % or less, the storage container was rinsed to perform the alcohol cleaning process. The rinsing was done 3 times with 1000 mL each time.

A 40% nitric acid solution was prepared as the acidic aqueous solution, and in a simple glove box under nitrogen atmosphere with oxygen concentration of 0.1 vol % or less, the storage container was rinsed to perform the acidic aqueous solution cleaning process. The rinsing was done 3 times with 1000 mL each time.

Ultrapure water (resistivity at 25° C.: 17 MΩ·cm) was prepared, and in a simple glove box under nitrogen atmosphere, the storage container was rinsed to perform the ultrapure water cleaning process. The rinsing was done 3 times with 1000 mL each time.

The cleaned storage container was filled with 1000 mL of ultrapure water (resistivity at 25° C.: 17 MΩ·cm), sealed, and left standing at 25° C. for 1 hour. Compared to the ultrapure water before filling, the increase in halogen ions was 24 mass ppb, and the increase in particles 0.5 μm or larger was 3 particles/mL.

The metal elements in the filled ultrapure water were quantified using ICP-MS, and the results are shown in Table 2 below. When observing the inside of the container with a Borescope, no yellowish precipitate was observed at all.

TABLE 2
(mass ppb)

| Na | Mg | K | Cr | Fe | Ni |
|---|---|---|---|---|---|
| 0.01 | 0.01 | 0.01 | 0.01 | 0.03 | 0.05 |

After cleaning the tin compound storage container, the following experiment was conducted in a clean zone to confirm its airtightness. Helium was filled into the container through an air-operated valve, and the filling and evacuation process (helium purge) was repeated 3 times, then helium was filled to 345 kPa. It was confirmed that there were no leaks over the next 4 hours.

The tin compound storage container was completely dried by vacuum suction at 60° C. for 24 hours, then cooled to 25° C., vacuum suctioned again, and helium was introduced up to 34.5 kPa.

The leakage from the VCR (valve seat) was measured using a helium detector connected with VCR adapters and KF adapters, resulting in 5×10⁻¹⁰Pa·m³/s.

### Comparative Example 1

Isopropyltris(dimethylamino)tin (99.8 mass % purity) was prepared. A 1000 mL SUS316L container was prepared as its storage container. In a glove box under nitrogen atmosphere, 500 mL of isopropyltris(dimethylamino)tin was placed in the storage container, left for 48 hours, then removed from the container, and the container was dried.

Methanol was prepared, and in a simple glove box under nitrogen atmosphere with oxygen concentration of 0.1 vol % or less, the storage container was rinsed to perform the alcohol cleaning process. The rinsing was done 3 times with 1000 mL each time.

n-Hexane was prepared, and in a simple glove box under nitrogen atmosphere with oxygen concentration of 0.1 vol % or less, the storage container was rinsed to perform the non-protic solvent cleaning process. The rinsing was done 3 times with 1000 mL each time.

A 40% nitric acid solution was prepared as the acidic aqueous solution, and in a simple glove box under nitrogen atmosphere with oxygen concentration of 0.1 vol % or less, the storage container was rinsed to perform the acidic aqueous solution cleaning process. The rinsing was done 3 times with 1000 mL each time.

Ultrapure water (resistivity at 25° C.: 17 MΩ·cm) was prepared, and in a simple glove box under nitrogen atmosphere, the storage container was rinsed to perform the ultrapure water cleaning process. The rinsing was done 3 times with 1000 mL each time.

As a result, white solids remained inside the container, and the container could not be cleaned. It is thought that tin oxide or tin hydroxide was produced by the reaction of the tin compound with alcohol and the water contained in the alcohol.

This cleaning method can efficiently and highly purify an apparatus for a tin compound after synthesizing or storing tin compounds, thereby suppressing the introduction or generation of impurities and fine particles when synthesizing or storing tin compounds and using the apparatus again. Tin compounds synthesized or stored using the apparatus which has been highly purified by this cleaning method are suitably used as raw materials for semiconductor and other applications.

While specific embodiments of the present invention have been shown in the above examples, these examples are merely illustrative and should not be interpreted in a limiting manner. Various modifications apparent to those skilled in the art are intended to be within the scope of the present invention.

We claim:

1. A method for cleaning an apparatus that has come into contact with a tin compound having formula (1), the method comprising at least steps (A) to (C), wherein step (B) is performed after step (A), and step (C) is performed after step (B):
(A) a step of cleaning the apparatus with a non-polar solvent,
(B) a step of cleaning the apparatus with an alcohol, and
(C) a step of cleaning the apparatus with ultrapure water having a resistivity of 17 MΩ·cm at 25° C.;
RₚSnXₘ (1)
wherein R is a hydrocarbon group, p is an integer from 1 to 3, X is a hydrolysable substituent group, and m=4−p.

2. The method for cleaning an apparatus according to claim 1, further comprising a step of cleaning the device with an acidic aqueous solution following the step of cleaning with an alcohol.

3. The method for cleaning an apparatus according to claim 1, wherein the non-polar solvent comprises at least one solvent selected from the group consisting of aromatic hydrocarbons, aliphatic hydrocarbons, saturated cyclic hydrocarbons, esters, linear ethers, and cyclic ethers.

4. The method for cleaning an apparatus according to claim 1, wherein the number of carbon atoms in the alcohol is 1 to 12.

5. The method for cleaning an apparatus according to claim 2, wherein the acidic aqueous solution is at least one solution selected from the group consisting of a hydrofluoric acid aqueous solution and a nitric acid aqueous solution.

6. The method for cleaning an apparatus according to claim 1, further comprising a drying step after the step of cleaning with ultrapure water.

7. The method for cleaning an apparatus according to claim 1, wherein the tin compound having formula (1) is t-butyltris(dimethylamino)tin, n-butyltris (dimethylamino)tin, t-butyltris(diethylamino)tin, di-t-butylbis (dimethylamino)tin, sec-butyltris (dimethylamino)tin, n-pentyltris (dimethylamino)tin, isobutyltris (dimethylamino)tin, isopropyltris (dimethylamino)tin, t-butyltri-t-butoxytin, n-butyltri-t-butoxytin, isopropyltri-t-butoxytin, isopropyltri-t-amyloxytin, t-butyltri-t-amyloxytin, 1-methyl-1-cyclopentyltris (dimethylamino)tin, or 1-methyl-1-cyclopentyltri-t-butoxytin.

8. An apparatus that has come into contact with the tin compound having formula (1) and has been cleaned by the method according to claim 1.

9. The apparatus according to claim 8, wherein when ultrapure water with a resistivity of 17 MΩ·cm at 25° C. is filled into the apparatus and left at 25° C. for 1 hour, an increase in the amount of dissolved halogen ions in the water is 100 mass ppb or less, an increase in the amount of each metal element sodium, potassium, magnesium, iron, chromium, and nickel is 1.5 mass ppb or less, and an increase in the amount of particles with a diameter of 0.5 μm or more is 100 particles/mL or less.

10. The apparatus according to claim 8, wherein when the tin compound having formula (1) is placed in the apparatus, sealed under an inert gas atmosphere, and stored at 25° C. for 3 months, a decrease in the purity of the tin compound is 0.1 mass % or less.

11. The apparatus according to claim 8, wherein the apparatus is a container for storing a tin compound.

12. The apparatus according to claim 8, wherein when the apparatus vacuum-dried and then filled with a gas with a pressure of 10 kPa, a valve seat leakage at a joint part measured by a gas detection device is 5×10⁻⁹Pa·m³/s or less.

13. An apparatus for a tin compound, wherein when ultrapure water with a resistivity of 17 MΩ·cm at 25° C. is filled into the apparatus and left at 25° C. for 1 hour, an increase in an amount of dissolved halogen ions in the water is 100 mass ppb or less, and a content of metal elements other than tin is 1.5 mass ppb or less.

14. An apparatus for a tin compound, wherein when ultrapure water with a resistivity of 17 MΩ·cm at 25° C. is filled into the apparatus and left at 25° C. for 1 hour an increase in the amount of particles with a diameter of 0.5 μm or more is 100 particles/mL or less.
